(19) United States
(12) Patent Application Publication
(10) Pub. No.: US 2013/0341661 A1
(43) Pub. Date: Dec. 26, 2013

(54) SEMICONDUCTOR LIGHT EMITTING ELEMENT

(71) Applicant: STANLEY ELECTRIC CO., LTD, Tokyo (JP)

(72) Inventor: Jiro HIGASHINO, Tokyo (JP)

(21) Appl. No.: 13/923,788

(22) Filed: Jun. 21, 2013

(30) Foreign Application Priority Data
Jun. 22, 2012 (JP) 2012-141292

(51) Int. Cl. H01L 33/60; H01L 33/00

(52) U.S. Cl. CPC H01L 33/60; H01L 33/0075
USPC 257/98; 438/43

(57) ABSTRACT

A semiconductor light emitting element comprising a light-reflecting layer formed on a support substrate, the light-reflecting layer having light reflectivity and including a bank portion having a particular plane pattern, a first electrode formed on the light-reflecting layer so as to surround the bank portion of the light-reflecting layer, the first electrode having light transparency, a stacked semiconductor layer formed on the first electrode, the stacked semiconductor layer, and a second electrode selectively formed on the stacked semiconductor layer, wherein the bank portion of the light-reflecting layer has a portion that overlaps the second electrode when viewed in plan, a portion that rises up from the first electrode when viewed in cross section, and a side wall surface that reflects light emitted from the active layer to a region of the second semiconductor layer in which the second electrode is not formed.

### CROSS REFERENCE TO RELATED APPLICATION

This application is based upon and claims the benefit of priority of the prior Japanese Patent Application No. 2012-141292, filed on Jun. 22, 2012, the entire contents of which are incorporated herein by reference.

### FIELD OF THE INVENTION

This invention relates to a semiconductor light emitting element and its manufacture.

### BACKGROUND

Light emitting diodes (LEDs) that use a nitride semiconductor such as GaN (gallium nitride) can emit ultraviolet light or blue light and can also emit white light by using a fluorescent material. LEDs that can emit white light with high power are used as, for example, illumination light sources such as light fixtures for vehicles.

Such semiconductor light emitting elements include a stacked semiconductor layer formed by successively stacking at least a p-type semiconductor layer, an active layer for light emission, and an n-type semiconductor layer. On the surface of the p-type semiconductor layer, a p-side electrode and a light-reflecting layer are formed over substantially the entire light emitting region. On the surface of the n-type semiconductor layer, an n-side electrode is selectively formed.

Electrons injected from the n-side electrode diffuse in the n-type semiconductor layer in a plane direction and reach the active layer. In the active layer, the electrons recombine with holes injected from the p-side electrode. The energy generated as a result of the recombination is radiated in the form of light (and heat). Part of the light emitted from the active layer directly reaches the surface of the n-type semiconductor layer and part of the light is reflected by the light-reflecting layer disposed on the p-type semiconductor layer side and then reaches the surface of the n-type semiconductor layer. The light that has reached a region of the surface of the n-type semiconductor layer in which the n-side electrode is not disposed is output to the outside of the semiconductor light emitting element. The light that has reached a region of the surface of the n-type semiconductor layer in which the n-side electrode is disposed is absorbed by the n-side electrode.

The ratio of the intensity of light output from the n-type semiconductor layer to the intensity of light emitted from the active layer is referred to as “light-output efficiency”. The light-output efficiency of the semiconductor light emitting element is desirably as high as possible.

An electric current that flows through the stacked semiconductor layer in a sectional direction flows through a region in which the n-side electrode and the p-side electrode face each other (a region below the n-side electrode) in a concentrated manner. Therefore, the intensity of the light emitted from the active layer reaches the highest in the region below the n-side electrode. However, most of light emitted in this region is absorbed by the n-side electrode, which may inhibit the improvement in the light-output efficiency of the semiconductor light emitting element.

An electrode structure in which the electric current flow is blocked in the region below the n-side electrode by not disposing the p-side electrode at a position below the n-side electrode has been proposed in, for example, Japanese Laid-open Patent Publication No. 2003-133588 and Japanese Laid-open Patent Publication No. 2011-129921. By employing such an electrode structure, an area in the active layer with relatively high emission intensity is shifted in a lateral direction from the region below the n-side electrode. Therefore, it is believed that most of light emitted from the area is output from the region of the n-type semiconductor layer in which the n-side electrode is not disposed, which improves the light-output efficiency of the semiconductor light emitting element.

### SUMMARY

According to one aspect of this invention, there is provided a semiconductor light emitting element comprising:

a light-reflecting layer formed on a support substrate, the light-reflecting layer having light reflectivity and including a bank portion having a particular plane pattern;

a first electrode formed on the light-reflecting layer so as to surround the bank portion of the light-reflecting layer, the first electrode having light transparency;

a stacked semiconductor layer formed on the first electrode, the stacked semiconductor layer being obtained by successively stacking at least a first semiconductor layer having a first conductivity type, a light emitting active layer, and a second semiconductor layer having a second conductivity type different from the first conductivity type; and

a second electrode selectively formed on the second semiconductor layer,

wherein the bank portion of the light-reflecting layer has a portion that overlaps the second electrode when viewed in plan, a portion that rises up from the first electrode when viewed in cross section, and a side wall surface that reflects light emitted from the active layer to a region of the second semiconductor layer in which the second electrode is not formed.

According to another aspect of this invention, there is provided a method of manufacturing a semiconductor light emitting element comprising steps of:

a) growing a stacked semiconductor layer on a growth substrate, the stacked semiconductor layer being obtained by successively stacking at least a first semiconductor layer having a first conductivity type, a light emitting active layer, and a second semiconductor layer having a second conductivity type;

b) forming a first electrode on a surface of the second semiconductor layer of the stacked semiconductor layer, the first electrode having light transparency and a particular plane pattern;

c) forming a groove in the surface of the second semiconductor layer of the stacked semiconductor layer by etching a region of the surface of the second semiconductor layer in which the first electrode is not formed;

d) forming a light-reflecting layer that fills the groove and covers the first electrode;

e) fixing the light-reflecting layer onto a support substrate via a bonding member, and detaching the growth substrate from the first semiconductor layer of the stacked semiconductor layer to expose a surface of the first semiconductor layer; and

f) selectively forming a second electrode on the exposed surface of the first semiconductor layer so that the second electrode has a portion that overlaps the groove when viewed in plan.

The object and advantages of the invention will be realized and attained by means of the elements and combinations particularly pointed out in the claims.

It is to be understood that both the foregoing general description and the following detailed description are exemplary and are not restrictive of the invention, as claimed.

### BRIEF DESCRIPTION OF THE DRAWINGS

FIGS. 1A and 1B are a cross-sectional view and a plan view, respectively, illustrating a semiconductor light emitting element of a reference example;

FIG. 1C is a photograph illustrating a surface of the semiconductor light emitting element of the reference example, the surface being observed in a light emitting state;

FIG. 1D is a cross-sectional view illustrating the vicinity of an n-side electrode layer of the semiconductor light emitting element of the reference example;

FIG. 2A is a cross-sectional view illustrating a semiconductor light emitting element according to a first embodiment;

FIG. 2B is a cross-sectional view illustrating the vicinity of an n-side electrode layer of the semiconductor light emitting element according to the first embodiment;

FIGS. 2C and 2D are plan views illustrating the semiconductor light emitting element according to the first embodiment;

FIGS. 3A to 3K are cross-sectional views illustrating the manufacturing process of the semiconductor light emitting element according to the first embodiment; and

FIGS. 4A to 4C are cross-sectional views respectively illustrating a semiconductor light emitting element according to a second embodiment, a semiconductor light emitting element according to a third embodiment, and a modification of the semiconductor light emitting element according to the third embodiment.

### DESCRIPTION OF THE PREFERRED EMBODIMENTS

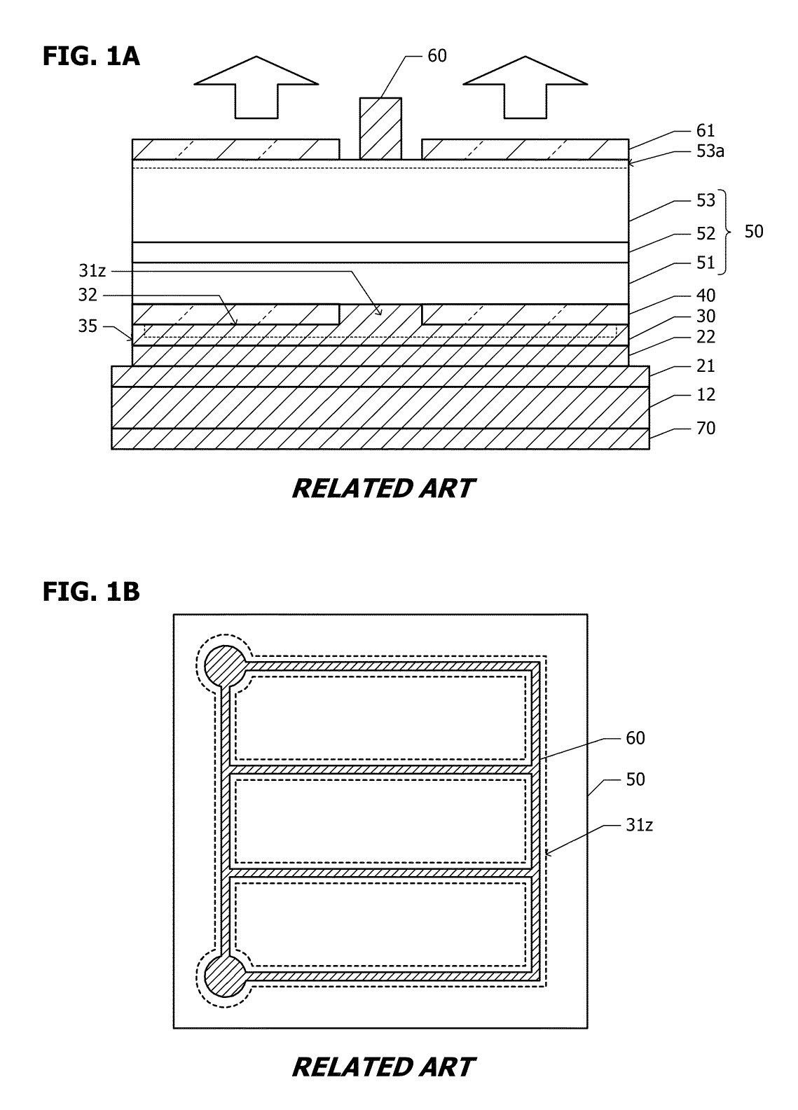

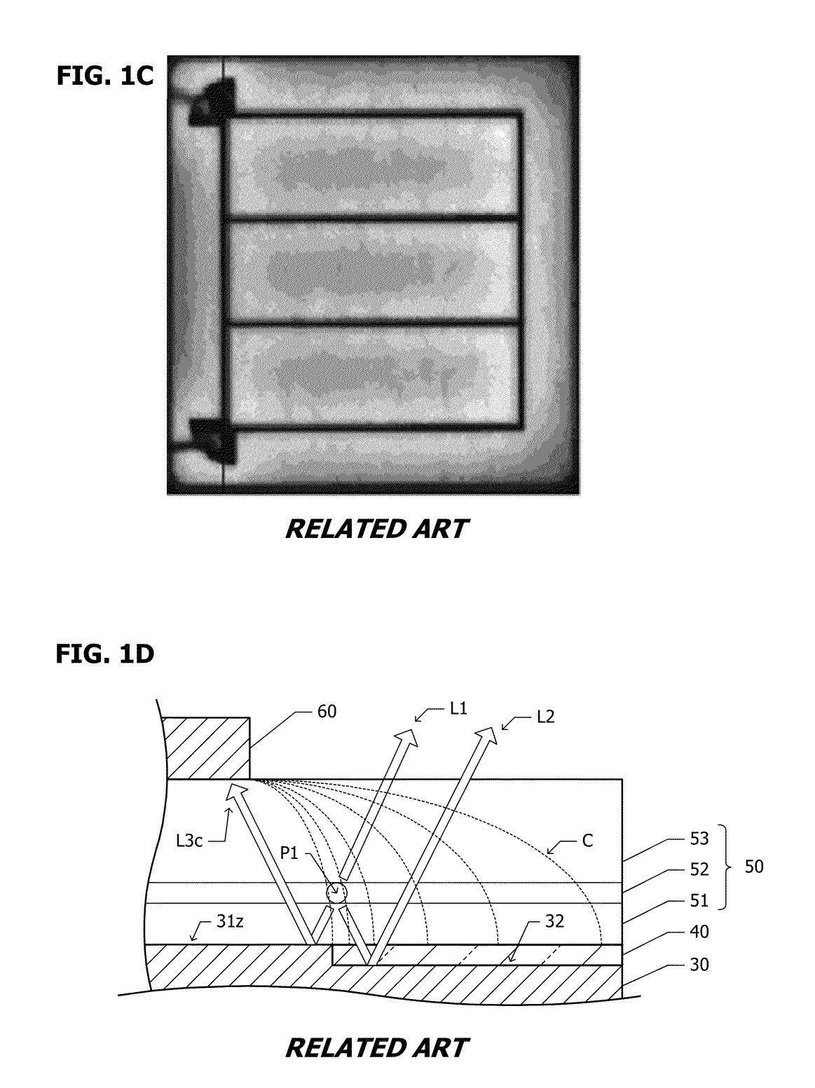

FIGS. 1A and 1B are a cross-sectional view and a plan view, respectively, illustrating a semiconductor light emitting element of a reference example. As illustrated in FIG. 1A, the semiconductor light emitting element of the reference example mainly includes an n-side electrode layer 60, a stacked semiconductor layer 50 composed of, for example, a GaN (gallium nitride)-based semiconductor material, a p-side electrode layer 40, and a light-reflecting layer 30. The stacked semiconductor layer 50 includes at least a p-type semiconductor layer 51, a light emitting active layer 52, and an n-type semiconductor layer 53, where the p-type is a first conductivity type and the n-type is a second conductivity type. A semiconductor light emitting element having such a structure is supported by a conductive support substrate 12 with bonding layers 21 and 22 disposed therebetween. A contact layer 70 is formed on the bottom surface of the support substrate 12.

The stacked semiconductor layer 50 has a structure in which the p-type semiconductor layer 51 and the n-type semiconductor layer 53 are disposed so as to sandwich the active layer 52. The p-type semiconductor layer 51 is composed of p-type GaN and, for example, magnesium (Mg) is added as a p-type dopant. The n-type semiconductor layer 53 is composed of n-type GaN and, for example, silicon (Si) is added as an n-type dopant. The structure of the stacked semiconductor layer 50 is not limited to the above-described three layers. For example, a cladding layer and a contact layer may be optionally inserted in order to improve the emission efficiency. The active layer 52 may be formed of a multilayer film (multiple quantum well structure).

A layer having fine irregularities, that is, a so-called micro-cone structure layer (MC layer) 53a may be formed on an outer (upper) surface of the n-type semiconductor layer 53 in order to improve the light-output efficiency. In this case, a protective film 61 having light transparency is formed to protect the MC layer 53a.

The p-side electrode layer 40 and the light-reflecting layer 30 are formed on an outer (lower) surface of the p-type semiconductor layer 51. The p-side electrode layer 40 is formed in a region of the surface of the p-type semiconductor layer 51, except for a region below the n-side electrode layer 60. The p-side electrode layer 40 is composed of a material having light transparency, such as indium tin oxide (ITO).

The light-reflecting layer 30 is formed so as to cover the p-side electrode layer 40 and reflects light emitted from the active layer 52 in an upward direction (the direction toward the surface of the n-type semiconductor layer 53). The light-reflecting layer 30 includes a convex portion 31z located in a region in which the p-side electrode layer 40 is not formed (the region below the n-side electrode layer 60) and a flat portion 32 which is a portion other than the convex portion 31z. The light-reflecting layer 30 is composed of a material having high reflectance at a wavelength of light emitted from the active layer 52, such as silver (Ag) or an Ag alloy.

A cap layer (or diffusion preventing layer) 35 may be formed on an outer (lower) surface and side surfaces of the light-reflecting layer 30 to suppress the migration from the light-reflecting layer 30 (Ag layer). The cap layer 35 suppresses the migration from the light-reflecting layer 30 (Ag layer) and has a layered structure containing a material that does not easily migrate, such as titanium (Ti) or platinum (Pt), which suppresses the migration from the cap layer 35.

The n-side electrode layer 60 is formed on an outer (upper) surface of the n-type semiconductor layer 53. For example, as illustrated in FIG. 1B, the n-side electrode layer 60 is formed so that the entire planar shape is a ladder-like shape. The n-side electrode layer 60 has a layered structure containing, for example, titanium (Ti) and aluminum (Al). In FIG. 1B, the n-side electrode layer 60 is indicated by a diagonally shaded pattern. The region in which the p-side electrode layer 40 (refer to FIG. 1A) is not formed, that is, the convex portion 31z of the light-reflecting layer 30 is indicated by a broken line. The convex portion 31z of the light-reflecting layer 30 is formed so as to encompass the n-side electrode layer 60 when viewed in plan. Alternatively, the convex portion 31z is formed so as to at least have a portion that overlaps the n-side electrode layer 60.

FIG. 1C is a photograph illustrating a surface of the semiconductor light emitting element of the reference example, the surface being observed in a light emitting state. In FIG. 1C, the shadow indicated by a ladder-like shape corresponds to the n-side electrode layer 60 (refer to FIG. 1B). A relatively white region located on the stacked semiconductor layer 50 (or n-type semiconductor layer 53, refer to FIG. 1B) corresponds to a region in which the emission intensity is high (the luminance is high). A relatively black region corresponds to a region in which the emission intensity is low (the luminance is low). As is clear from this photograph, the emission intensity is relatively high in a region close to the n-side electrode layer on the surface of the stacked semiconductor layer and is relatively low in a region distant from the n-side electrode layer.

FIG. 1D is a cross-sectional view illustrating the vicinity of the n-side electrode layer 60 of the semiconductor light emitting element of the reference example. In FIG. 1D, the MC layer 53a and the protective film 61 illustrated in FIG. 1A are omitted.

Electrons injected from the n-side electrode layer 60 diffuse in the n-type semiconductor layer 53 in a plane direction (lateral direction) and reach the active layer 52. In the active layer 52, the electrons recombine with holes injected from the p-side electrode layer 40. The energy generated as a result of the recombination is radiated in the form of light (and heat).

Herein, electric current C flows through the stacked semiconductor layer 50 from the p-side electrode layer 40 toward the n-side electrode layer 60.

The current density in the active layer 52 is relatively high at a position close to the n-side electrode layer 60 and decreases as the distance from the n-side electrode layer 60 increases. In other words, the emission intensity in the active layer 52 is relatively high at a position close to the n-side electrode layer 60 and decreases as the distance from the n-side electrode layer 60 increases. The position at which the emission intensity (current density) is the highest in the active layer 52 is referred to as P1.

Part of the light emitted from the position P1 in the active layer 52 is emitted in the direction (the upward direction in FIG. 1D) toward the surface of the n-type semiconductor layer 53 and the other part of the light is emitted in the direction (the downward direction in FIG. 1D) toward the surface of the p-type semiconductor layer 51. The light emitted in the direction toward the surface of the n-type semiconductor layer 53 is output from a region not covered with the n-side electrode layer 60 on the surface of the n-type semiconductor layer 53 (light L1).

Part of the light emitted in the direction toward the surface of the p-type semiconductor layer 51 is, for example, reflected by the flat portion 32 of the light-reflecting layer 30 and then output from the region not covered with the n-side electrode layer 60 on the surface of the n-type semiconductor layer 53 (light L2). The other part of the light emitted in the direction toward the surface of the p-type semiconductor layer 51 is, for example, reflected by the upper surface of the convex portion 31z of the light-reflecting layer 30 and then absorbed by the n-side electrode layer 60 (light L3c).

To improve the light-output efficiency of the semiconductor light emitting element, it is desirable that the light having relatively high emission intensity, in particular, the light L3c emitted from the position P1 is output in a larger amount from the region not covered with the n-side electrode layer 60 on the surface of the n-type semiconductor layer 53. The inventor of the present invention has investigated a structure of the semiconductor light emitting element in which the light L3c which would otherwise be absorbed by the n-side electrode layer 60 can be output in a larger amount from the region not covered with the n-side electrode layer 60 on the surface of the n-type semiconductor layer 53, in particular, a structure of the light-reflecting layer.

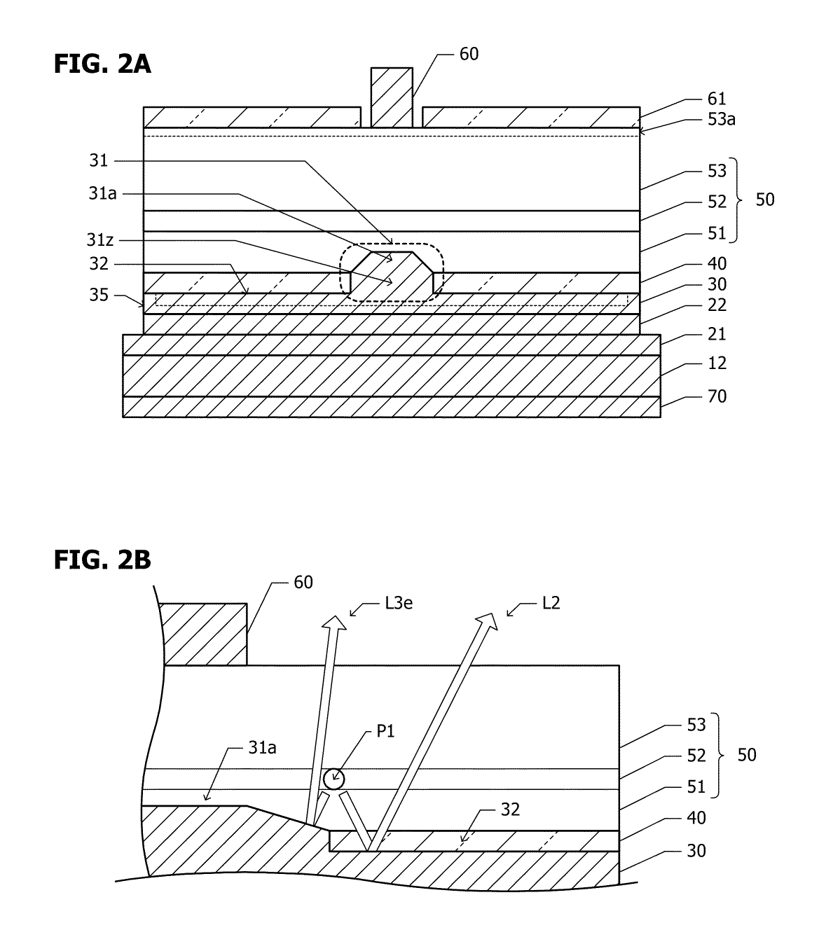

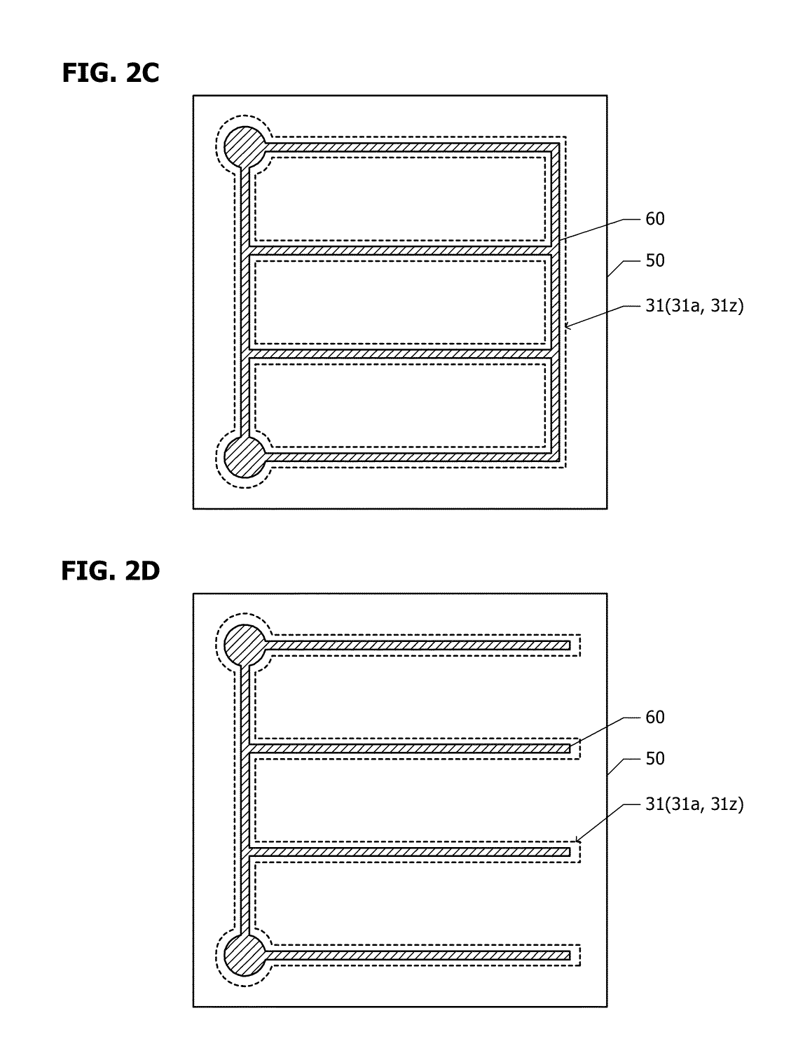

FIG. 2A is a cross-sectional view illustrating a semiconductor light emitting element according to a first embodiment. The semiconductor light emitting element substantially has the same structure as that of the semiconductor light emitting element of the reference example, except for the structure of the light-reflecting layer 30.

A light-reflecting layer 30 according to the first embodiment is formed so that the convex portion 31z projects from the p-side electrode layer 40. That is, the convex portion 31z of the light-reflecting layer 30 includes a portion (rising portion) 31a that rises up from the p-side electrode layer 40. The rising portion 31a has, for example, a tapered cross-sectional shape whose width gradually decreases in the upward direction (the direction toward the surface of the n-type semiconductor layer 53). Here, a portion including the convex portion 31z and the rising portion 31a is referred to as a bank portion 31.

FIG. 2B is a cross-sectional view illustrating the vicinity of the n-side electrode layer 60 of the semiconductor light emitting element according to the first embodiment. In FIG. 2B, the MC layer 53a and the protective film 61 illustrated in FIG. 2A are omitted.

In the first embodiment, part of the light emitted from the position P1 (at which the emission intensity is the highest) in the active layer 52 toward the surface of the p-type semiconductor layer 51 is reflected by a side wall surface of the rising portion 31a of the bank portion and then output from the region not covered with the n-side electrode layer 60 on the surface of the n-type semiconductor layer 53 (light L3e). Since the light-reflecting layer 30 according to the first embodiment includes, in the bank portion, the rising portion 31a that rises up from the p-side electrode layer 40, the light which would otherwise be reflected by the upper surface of the rising portion of the bank portion and absorbed by the n-side electrode layer in the reference example (light L3c, refer to FIG. 1D) is reflected by the side wall surface of the rising portion of the bank portion and output from the region of the n-type semiconductor layer in which the n-side electrode is not disposed (light L3e). It is believed that, by disposing the light-reflecting layer having such a structure, the light-output efficiency of the semiconductor light emitting element can be improved.

FIGS. 2C and 2D are plan views illustrating the semiconductor light emitting element according to the first embodiment. As illustrated in FIG. 2C, the bank portion 31 (indicated by a broken line in FIGS. 2C and 2D) including the convex portion 31z and rising portion 31a in the light-reflecting layer 30 is formed so as to encompass the n-side electrode layer 60 when viewed in plan. Alternatively, the bank portion 31 is formed so as to at least have a portion that overlaps the n-side electrode layer 60.

The planar shape of the n-side electrode layer 60 is not limited to the ladder-like shape, and may be a comb-like shape as illustrated in FIG. 2D or a lattice shape. The n-side electrode layer 60 preferably has a planar shape including at least a portion formed in a striped pattern. Also in this case, the bank portion 31 of the light-reflecting layer 30 is preferably formed so as to have a planar shape corresponding to that of the n-side electrode layer 60 and encompass the n-side electrode layer 60.

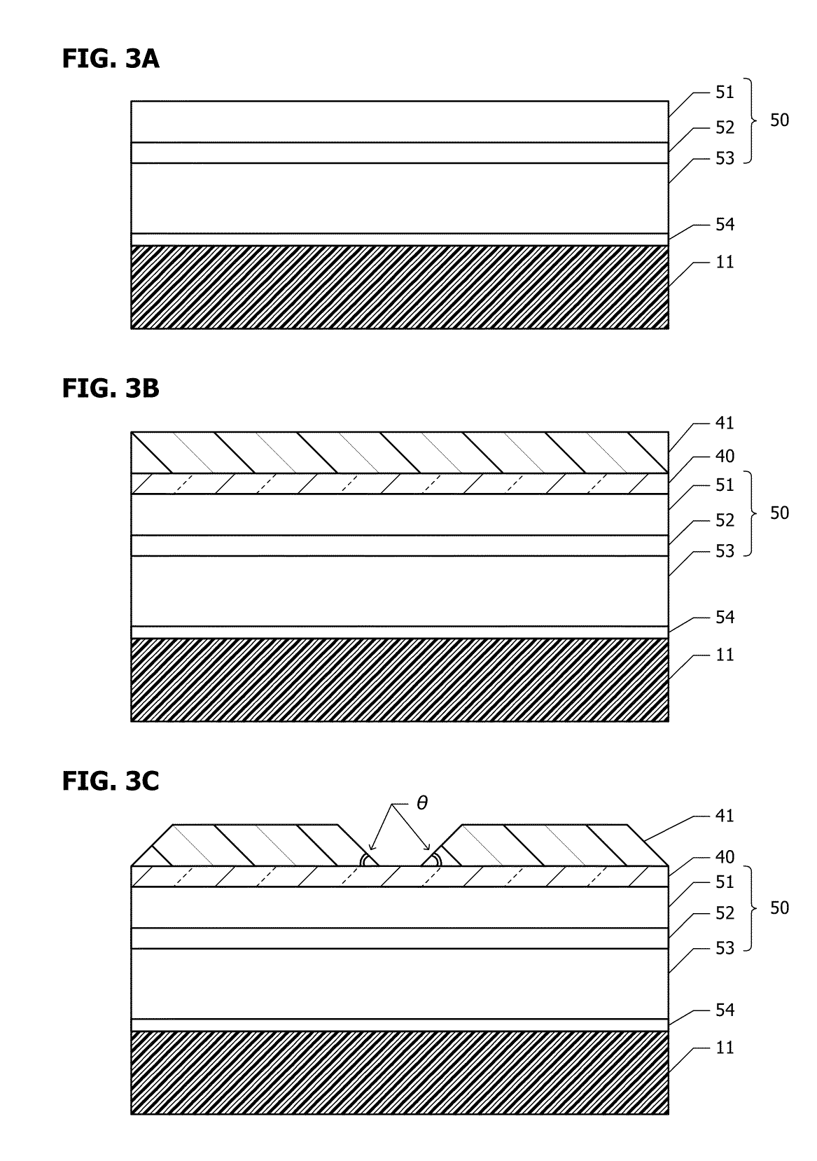

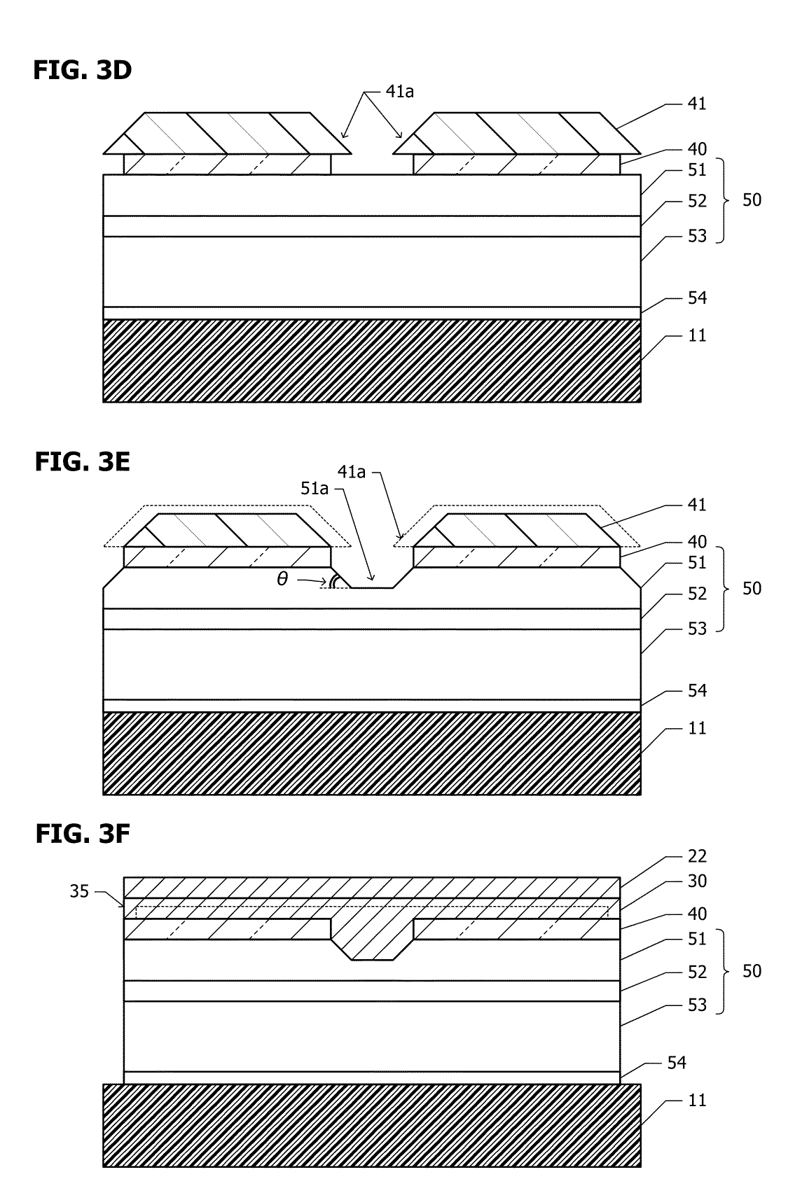

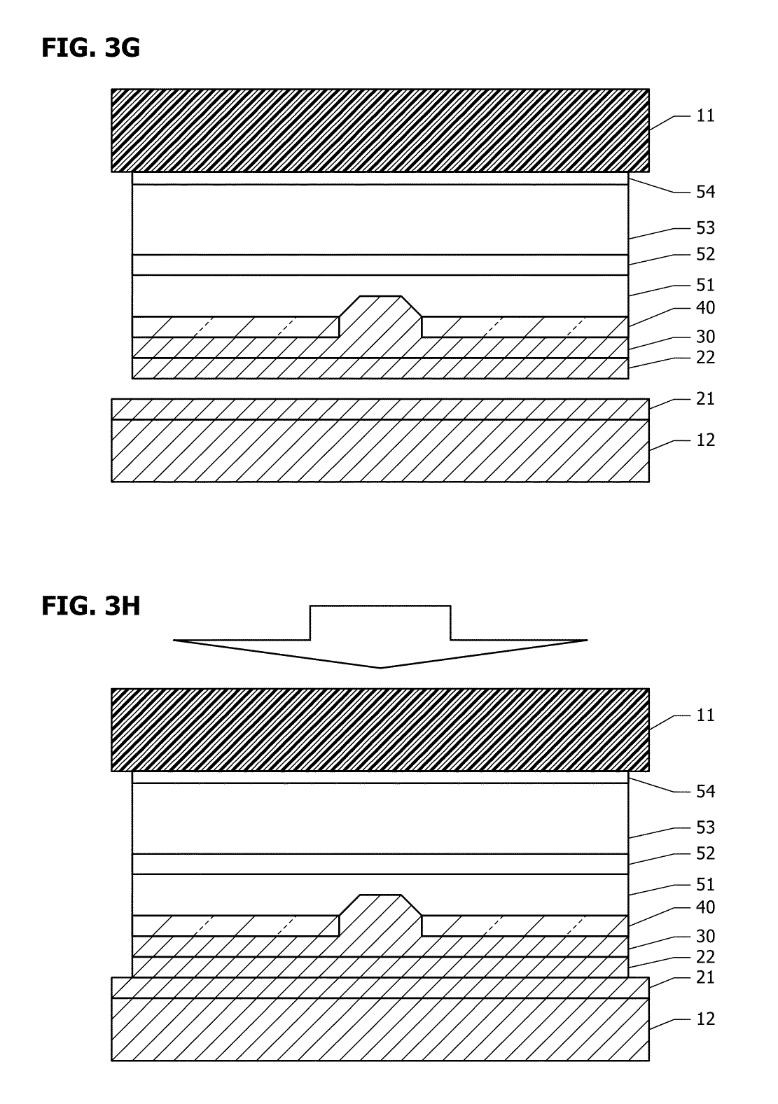

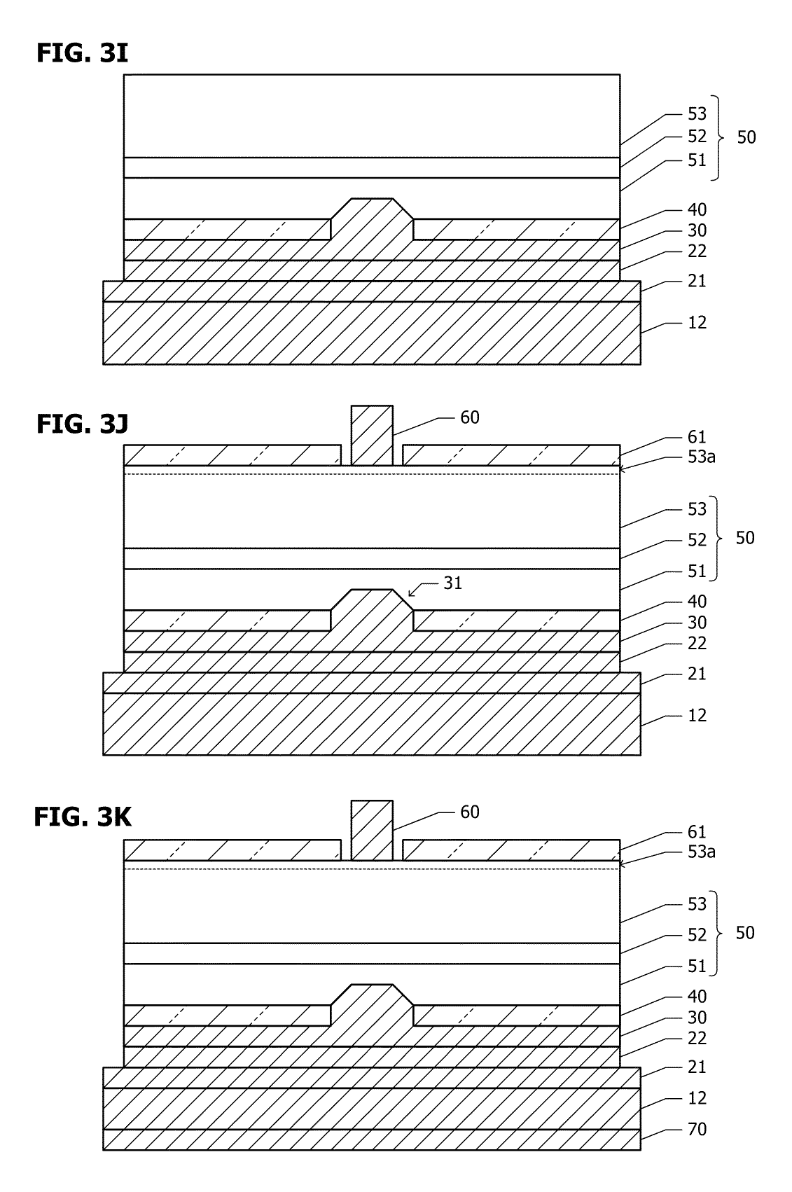

A method of manufacturing the semiconductor light emitting element according to the first embodiment will now be described with reference to FIGS. 3A to 3K. The size ratio of constituent members in the drawings is different from that of actual constituent members.

First, a step of forming a stacked semiconductor layer is conducted. A stacked body 54 including a buffer layer and a base layer and a stacked semiconductor layer 50 including a first semiconductor layer (n-type semiconductor layer) 53, an active layer 52, and a second semiconductor layer (p-type semiconductor layer) 51 are stacked on a c-plane sapphire growth substrate 11 by metal-organic chemical vapor deposition (MOCVD) to prepare an optical semiconductor epiwafer illustrated in FIG. 3A. Each of the layers is composed of a nitride semiconductor represented by AlₓIn_{y}Ga_{1-x-y}N (0x1, 0≦y 1). For example, Si serving as an n-type dopant or Mg serving as a p-type dopant may be optionally added to each of the layers. The structure of the stacked semiconductor layer 50 is not limited to the above-described three layers. For example, a cladding layer and a contact layer may be optionally inserted in order to improve the emission efficiency. The active layer 52 may be formed of a multilayer film (multiple quantum well structure).

Next, a step of forming a semiconductor element from the semiconductor epiwafer is conducted. First, the p-type semiconductor layer 51 is activated. The p-type semiconductor layer 51 has a magnesium-hydrogen (Mg—H) bond because hydrogen is mixed in the layer during the growth process. In such a state, magnesium does not function as a dopant and the p-type semiconductor layer 51 has high resistance. Therefore, an activation step of expelling the hydrogen from the p-type semiconductor layer 51 is required. Specifically, a heat treatment is performed at 400° C. or more in a vacuum atmosphere or an inert gas atmosphere using a heat treatment furnace.

Subsequently, as illustrated in FIG. 3B, an ITO film 40 having a thickness of about 15 nm is formed on the entire surface of the p-type semiconductor layer 51 by RF sputtering. A resist material is then applied onto the entire surface of the ITO film 40 by spin coating or the like and heat-treated at 90° C. for 90 seconds to form a resist film 41. In this embodiment, OFPR 800 manufactured by TOKYO OHKA KOGYO CO., LTD. is used as the resist material.

Subsequently, the resist film 41 is exposed and developed using a photomask having a desired pattern. A post-baking treatment is then performed at 110° C. for 5 minutes to form the resist film 41 patterned as illustrated in FIG. 3C. In this embodiment, the patterned resist film 41 is formed in a tapered cross-sectional shape whose width gradually decreases in the upward direction. The patterned resist film 41 is also formed so that the taper angle 8 of the resist film 41 (the angle of the side wall surface relative to the bottom surface of the resist film 41) is about 60°. Under the conditions of this embodiment, for example, when a post-baking treatment is performed at 130° C. for 5 minutes, the taper angle 8 of the resist film 41 is about 40°. Furthermore, since the cross-sectional shape of the resist film 41 varies depending on, for example, the resist material and pattern size, it is preferable to suitably adjust the post-baking treatment conditions.

Subsequently, as illustrated in FIG. 3D, the ITO film 40 is wet-etched using a generally used etchant for ITO to shape the ITO film 40 having a pattern corresponding to the pattern of the resist film 41. Here, since the side etching of the ITO film 40 also occurs, the pattern size of the ITO film 40 is smaller than that of the resist film 41. The edge region of the resist film 41 protrudes from the ITO film 40 like an overhang (overhang portion 41a). In this embodiment, the width of the ITO film 40 subjected to side etching (the length of the overhang portion 41a of the resist film 41) is about 0.15 μm. Through the above processes, a patterned ITO film, that is, a p-side electrode layer 40 is formed.

Subsequently, as illustrated in FIG. 3E, the p-type semiconductor layer 51 is etched by reactive ion etching (RIE) to form a groove 51a in the surface of the p-type semiconductor layer 51. In this embodiment, the RIE conditions are as follows.

Reactive gas: Cl₂ (chlorine)

Reactive gas flow rate: about 100 SCCM

Pressure in reaction container: about 1 Pa

Source/bias power: about 500 W/50 W

Etching time: about 50 seconds

The etching rate of the p-type semiconductor layer 51 under these RIE conditions is about 160 nm/min, and the depth of the p-type semiconductor layer 51 (groove 51a) etched is about 130 nm. The surface roughness (surface morphology) of the bottom surface and side surfaces of the groove 51a formed in the surface of the p-type semiconductor layer 51 by etching is improved compared with the surface roughness of a region of the p-type semiconductor layer 51 not subjected to etching.

In this RIE treatment, the p-type semiconductor layer 51 is etched while at the same time the resist film 41 is etched. In FIG. 3E, the resist film before the etching is indicated by a broken line. The etching rate of the resist film 41 under the RIE conditions of this embodiment is about 160 nm/min, which is substantially the same as the etching rate of the p-type semiconductor layer 51.

In this RIE treatment, a region of the p-type semiconductor layer 51 that is not masked by the resist film 41 (in particular, the overhang portion 41a), that is, a region that is not shaded by the overhang portion 41a is etched first. As the RIE treatment proceeds, the resist film 41 is also etched and the region of the p-type semiconductor layer 51 that is masked by the overhang portion 41a is gradually exposed. Then, a region of the p-type semiconductor layer 51 that is exposed without being masked by the overhang portion 41a is sequentially etched.

In this embodiment, the etching rate of the resist film 41 and the etching rate of the p-type semiconductor layer 51 are substantially the same. Therefore, the p-type semiconductor layer 51 left after the etching has a tapered cross-sectional shape whose taper angle 8 (about 60°) is substantially the same as that of the resist film 41. On the other hand, the groove 51a formed in the surface of the p-type semiconductor layer 51 has a tapered cross-sectional shape whose width decreases in the downward direction (the direction toward the surface of the growth substrate 11).

By controlling the reactive gas flow rate or bias power in the RIE treatment, the cross-sectional shape of the p-type semiconductor layer 51 left after the etching or the cross-sectional shape of the groove 51a can be adjusted. For example, when the reactive gas flow rate is increased or the bias power is decreased, the etching rate of the p-type semiconductor layer 51 becomes higher than the etching rate of the resist film 41. As a result, the taper angle of the p-type semiconductor layer 51 left after the etching becomes larger than the taper angle of the resist film 41. When the reactive gas flow rate is decreased or the bias power is increased, the etching rate of the p-type semiconductor layer 51 becomes lower than the etching rate of the resist film 41. As a result, the taper angle of the p-type semiconductor layer 51 left after the etching becomes smaller than the taper angle of the resist film 41. Furthermore, by continuously changing the reactive gas flow rate or bias power during the RIE treatment, the side wall surface of the p-type semiconductor layer 51 left after the etching can be formed so as to have a convex or concave arc shape.

Through the above processes, the groove 51a is formed in the surface of the p-type semiconductor layer 51. The resist film 41 is removed after the groove 51a is formed in the surface of the p-type semiconductor layer 51.

Subsequently, as illustrated in FIG. 3F, a light-reflecting layer 30 is formed by electron beam deposition so as to fill the groove of the p-type semiconductor layer 51 and also cover the p-side electrode layer 40. In this embodiment, the light-reflecting layer 30 is formed using silver so as to have a thickness of about 150 nm from the bottom surface of the groove of the p-type semiconductor layer 51. A portion of the light-reflecting layer 30 embedded in the groove of the p-type semiconductor layer 51 corresponds to a bank portion 31 (or rising portion 31a, refer to FIGS. 2A and 2B) in the light-reflecting layer 30 of the semiconductor light emitting element to be manufactured in the end. Herein, a cap layer 35 that has a layered structure of titanium (Ti) and platinum (Pt) and covers the light-reflecting layer 30 (Ag layer) may be formed.

A bonding layer 22 having a layered structure of titanium (thickness: 50 nm), platinum (thickness: 200 nm) and gold (thickness: 1200 nm) is then formed by electron beam deposition. The stacked structural body that is formed on the growth substrate 11 and obtained by successively stacking the stacked semiconductor layer 50, the p-side electrode layer 40, and the light-reflecting layer 30 is partitioned in a desired semiconductor light emitting element size by RIE or the like to perform element isolation.

Subsequently, as illustrated in FIG. 3G, the stacked structural body formed on the growth substrate 11 and a support substrate 12 are bonded to each other. The support substrate 12 can be composed of, for example, n-type Si or SiC (silicon carbide). A bonding layer 21 is formed on one surface of the support substrate 12. The bonding layer 21 can be obtained by alternately stacking gold (Au) and tin (Sn). Note that the materials of the bonding layer 21 are not limited to gold and tin.

The support substrate 12 on which the bonding layer 21 has been formed is prepared, the bonding layer 22 on the growth substrate 11 and the bonding layer 21 on the support substrate 12 are laid on top of one another, and heat and pressure are applied to the substrates using a wafer bonder. As a result, Au—Sn eutectic is formed at the bonding interface and the bonding of the substrates is achieved. In this embodiment, the bonding is performed at a pressure of 350 kg at a temperature of 320° C. for 5 minutes (thermocompression bonding). Thus, a stacked structural body obtained by successively stacking the light-reflecting layer 30, the p-side electrode layer 40, and the stacked semiconductor layer 50 is fixed on the support substrate 12.

Next, a step of detaching the growth substrate is conducted. In this step, a laser lift-off (LLO) method is used in which the growth substrate 11 is detached from the stacked semiconductor layer 50 by irradiating the bottom surface of the growth substrate 11 on which the stacked semiconductor layer is not grown, with a high power pulsed laser having energy that decomposes GaN, such as an excimer laser. An example of the laser is a KrF (krypton fluoride) excimer laser with an irradiation energy of about 800 mJ/cm² and a wavelength of about 248 nm.

As illustrated in FIG. 3H, part of the stacked body 54 including the buffer layer and the base layer is decomposed by irradiating the bottom surface of the growth substrate 11 with an excimer laser to detach the growth substrate 11 and the stacked semiconductor layer 50 from each other, which provides a state illustrated in FIG. 3I. Gallium (Ga) generated as a result of the laser lift-off is removed using hot water or the like, and then a surface treatment is performed with hydrochloric acid. Consequently, the n-type semiconductor layer 53 is exposed. The surface treatment can be performed with any material that can etch a nitride semiconductor, e.g., an acid or alkali agent such as phosphoric acid, sulfuric acid, potassium hydroxide, or sodium hydroxide. The surface treatment may be performed by, for example, polishing or dry etching that uses argon plasma or chlorine-based plasma. Furthermore, the surface of the n-type semiconductor layer 53 is smoothened using a chemical mechanical polishing (CMP) apparatus or the like to remove laser marks and a layer damaged by the laser.

Subsequently, as illustrated in FIG. 33, an MC layer 53a is formed on the exposed surface of the n-type semiconductor layer 53. The MC layer 53a can be formed by, for example, an RIE treatment or a treatment that uses a chemical solution such as phenyltrimethylammonium hydroxide (TMAH) or potassium hydroxide (KOH). In this embodiment, an MC layer 53a having a thickness of about 1 μm is formed using TMAH.

Subsequently, an n-side electrode layer 60 having a desired pattern is formed on the surface of the n-type semiconductor layer 53 (MC layer 53a) and a protective film 61 is formed in a region in which the n-side electrode layer 60 is not formed. The protective film 61 can be formed by, for example, sputtering or electron beam deposition. In this embodiment, a silicon dioxide film having a thickness of about 300 nm is formed by sputtering. The n-side electrode layer 60 can be formed by, for example, lift-off. In this embodiment, a layered electrode including titanium (thickness: 1 nm), aluminum (thickness: 200 nm), titanium (thickness: 100 nm), platinum (thickness: 200 nm) and gold (thickness: 2500 nm) is formed. The n-side electrode layer 60 is formed so as to overlap at least the bank portion 31 (which corresponds to the groove 51a formed in the surface of the p-type semiconductor layer 51) of the light-reflecting layer 30 when viewed in plan. The n-side electrode layer 60 is preferably formed so as to be encompassed by the bank portion 31 of the light-reflecting layer 30 when viewed in plan (refer to FIG. 1B).

Subsequently, as illustrated in FIG. 3K, the thickness of the support substrate 12 is decreased by a grinding and polishing treatment, and then a contact layer 70 is formed on the bottom surface of the support substrate 12. The contact layer 70 is formed by successively forming films of Pt/Ti/Pt/Au using, for example, electron beam deposition. The films of Pt/Ti/Pt/Au have thicknesses of about 80/120/150/200 nm, respectively.

Finally, the support substrate 12 is divided by laser scribing or dicing. Thus, a semiconductor light emitting element according to the first embodiment is completed. Note that, when a blue light emitting element composed of GaN is used as a white light emitting element, a yellow fluorescent material is added to a filling resin that seals the light emitting element.

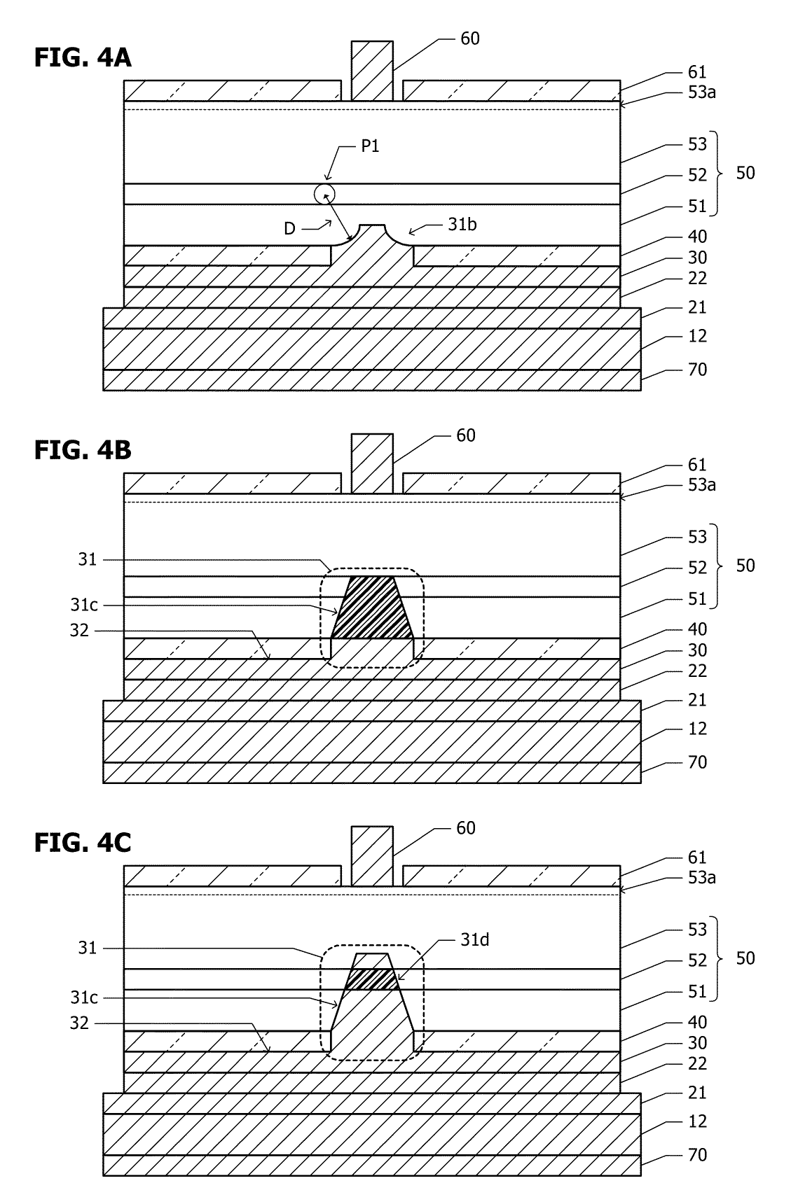

FIG. 4A is a cross-sectional view illustrating a semiconductor light emitting element according to a second embodiment. This semiconductor light emitting element has substantially the same structure as that of the semiconductor light emitting element according to the first embodiment, except for the bank portion of the light-reflecting layer, in particular, the shape of the rising portion.

The cross-sectional shape of the bank portion of the light-reflecting layer, in particular, the rising portion is not limited to the tapered shape whose width gradually decreases in the upward direction as in the first embodiment, and may be a rectangular shape. In other words, the bank portion of the light-reflecting layer may have any shape as long as the bank portion has a side wall surface that reflects light emitted from the active layer to a region of the n-type semiconductor layer in which the n-side electrode layer is not formed.

The cross-sectional shape of the rising portion of the bank portion is desirably a shape in which the side wall surface has a concave arc shape as illustrated in FIG. 4A. In other words, the shape of the side wall surface of the bank portion 31 of the light-reflecting layer 30, in particular, a rising portion 31b is desirably a shape that causes constructive interference between the light L1 (refer to FIG. 1D) and the light L3e (refer to FIG. 1D). The light L1 is light that is emitted from the position P1, at which the emission intensity is the highest, in the active layer 52 toward the surface of the n-type semiconductor layer 53. The light L3e is light that is emitted from the position P1 toward the surface of the p-type semiconductor layer 51, reflected by the rising portion 31b, and then propagated toward the surface of the n-type semiconductor layer 53. Herein, the distance from the position P1, at which the emission intensity is the highest, in the active layer 52 to the side wall surface of the rising portion 31b is assumed to be D.

In this embodiment, the wavelength λ₀ of the light emitted from the active layer 52 (nitride semiconductor) is about 455 nm. The effective refractive index n of the stacked semiconductor layer 50 (nitride semiconductor) is about 2.4. Therefore, the wavelength λ, of the light that is emitted from the active layer 52 and propagated through the stacked semiconductor layer 50 is about 189.6 nm (=λ₀/n). The constructive interference condition between the light L1 and the light L3e is D=(2 m+1)λ/4 (m is an integer of 0 or more). Thus, in this embodiment, the side wall surface of the rising portion 31b is desirably formed so that the distance D from the position P1 to the side wall surface of the rising portion 31b is, for example, 47.4 nm (m=0) or 142.2 nm (m=1). When the rising portion 31b (bank portion) has such a shape, the light emitted from the position P1 in the active layer 52 will be efficiently output from the surface of the n-type semiconductor layer 53.

The shape of the side wall surface of the rising portion 31b can be adjusted by controlling the reactive gas flow rate or bias power during the formation of the groove 51a by subjecting the p-type semiconductor layer 51 to an RIE treatment in the method of manufacturing the semiconductor light emitting element described in the first embodiment (refer to FIG. 3E). The groove (rising portion 31b) in the second embodiment can be formed by, for example, changing the ratio of the etching rate of the p-type semiconductor layer 51 to the etching rate of the resist film 41 from 1.5 to 0.1 in stages.

FIG. 4B is a cross-sectional view illustrating a semiconductor light emitting element according to a third embodiment. The semiconductor light emitting element has substantially the same structure as that of the semiconductor light emitting element according to the first embodiment, except for the bank portion of the light-reflecting layer, in particular, the shape of the rising portion.

As illustrated in FIG. 4B, the bank portion 31 of the light-reflecting layer 30, in particular, a rising portion 31c may be composed of a material (e.g., silicon dioxide) different from the material (e.g., silver) of the flat portion 32. The rising portion 31c may be formed so as to penetrate through the p-type semiconductor layer 51 and the active layer 52. When the rising portion 31c penetrates through the p-type semiconductor layer 51 and the active layer 52 and is formed to a higher position, a larger amount of light emitted from the active layer 52 will be reflected to a region of the n-type semiconductor layer 53 in which the n-side electrode layer 60 is not formed, without being absorbed by the n-side electrode layer 60.

The inventor of the present invention has measured the light-output efficiency of the semiconductor light emitting element according to the third embodiment and the light-output efficiency of the semiconductor light emitting element (refer to FIG. 1A) of the reference example in which the light-reflecting layer does not have a rising portion, and the comparison and investigation of the light-output efficiencies have been made. It has been found from the results that the light-output efficiency in the third embodiment is higher than the light-output efficiency in the reference example by about 4%. In view of the measurement results, it can be considered that the light which would otherwise be absorbed by the n-side electrode layer in the reference example is efficiently output from the surface of the n-type semiconductor layer on which the n-side electrode layer is not disposed in the third embodiment.

FIG. 4C is a cross-sectional view illustrating a modification of the semiconductor light emitting element according to the third embodiment. A rising portion 31c of the light-reflecting layer 30 may be formed to a higher position than the rising portion illustrated in FIG. 4B, and part of the rising portion 31c may be composed of a material different from a material of the other part of the rising portion 31c. In the case where the rising portion 31c is formed so as to penetrate through the active layer 52, at least a portion 31d of the rising portion 31c corresponding to the active layer 52 needs to be composed of an insulating material to prevent the electrical short circuit of the active layer 52.

The embodiments of the present invention have been described, but the present invention is not limited to the embodiments. For example, by combining the second embodiment and the third embodiment, a bank portion having an arc-shaped side wall surface may be formed so as to penetrate through the p-type semiconductor layer and the active layer.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority and inferiority of the invention. Although the embodiments of the invention have been described in detail, it should be understood that the various changes, substitutions, and alterations could be made hereto without departing from the spirit and scope of the invention.

1. A semiconductor light emitting element comprising:
a light-reflecting layer formed on a support substrate, the light-reflecting layer having light reflectivity and including a bank portion having a particular plane pattern;
a first electrode formed on the light-reflecting layer so as to surround the bank portion of the light-reflecting layer, the first electrode having light transparency;
a stacked semiconductor layer formed on the first electrode, the stacked semiconductor layer being obtained by successively stacking at least a first semiconductor layer having a first conductivity type, a light emitting active layer, and a second semiconductor layer having a second conductivity type different from the first conductivity type; and
a second electrode selectively formed on the second semiconductor layer,
wherein the bank portion of the light-reflecting layer has a portion that overlaps the second electrode when viewed in plan, a portion that rises up from the first electrode when viewed in cross section, and a side wall surface that reflects light emitted from the active layer to a region of the second semiconductor layer in which the second electrode is not formed.

2. The semiconductor light emitting element according to claim 1, wherein the bank portion of the light-reflecting layer has a width that gradually decreases in an upward direction when viewed in cross section.

3. The semiconductor light emitting element according to claim 2, wherein the side wall surface of the bank portion of the light-reflecting layer has a concave arc shape.

4. The semiconductor light emitting element according to claim 1, wherein the bank portion of the light-reflecting layer penetrates through the first semiconductor layer and the active layer when viewed in cross section, and at least a portion of the bank portion corresponding to the active layer contains an insulating material.

5. The semiconductor light emitting element according to claim 1, wherein the bank portion of the light-reflecting layer has a plane pattern in which the bank portion encompasses the second electrode when viewed in plan.

6. The semiconductor light emitting element according to claim 5, wherein the second electrode and the bank portion of the light-reflecting layer each have a portion formed in a striped pattern when viewed in plan.

7. The semiconductor light emitting element according to claim 1, further comprising a cap layer,
wherein the light-reflecting layer contains Ag, and
the cap layer covers the light-reflecting layer to suppress migration from the light-reflecting layer.

8. A method of manufacturing a semiconductor light emitting element comprising steps of:
a) growing a stacked semiconductor layer on a growth substrate, the stacked semiconductor layer being obtained by successively stacking at least a first semiconductor layer having a first conductivity type, a light emitting active layer, and a second semiconductor layer having a second conductivity type;
b) forming a first electrode on a surface of the second semiconductor layer of the stacked semiconductor layer, the first electrode having light transparency and a particular plane pattern;
c) forming a groove in the surface of the second semiconductor layer of the stacked semiconductor layer by etching a region of the surface of the second semiconductor layer in which the first electrode is not formed;
d) forming a light-reflecting layer that fills the groove and covers the first electrode;
e) fixing the light-reflecting layer onto a support substrate via a bonding member, and detaching the growth substrate from the first semiconductor layer of the stacked semiconductor layer to expose a surface of the first semiconductor layer; and
f) selectively forming a second electrode on the exposed surface of the first semiconductor layer so that the second electrode has a portion that overlaps the groove when viewed in plan.

9. The method of manufacturing a semiconductor light emitting element according to claim 8,
wherein the step b) includes substeps of:
b1) uniformly forming the first electrode on the surface of the second semiconductor layer of the stacked semiconductor layer,
b2) forming a resist film having a particular plane pattern on the first electrode, and
b3) shaping the first electrode by etching a region of the first electrode in which the resist film is not covered and a region of the first electrode corresponding to an edge region of the resist film to provide a state in which the edge region of the resist film protrudes from the first electrode, and
in the step C), the groove is formed by etching the second semiconductor layer while etching the edge region of the resist film that protrudes from the first electrode so that the width of the groove gradually decreases in a depth direction.

10. The method of manufacturing a semiconductor light emitting element according to claim 9, wherein, in the step c), the groove is formed by etching the edge region of the resist film and the second semiconductor layer with change in etching conditions.
